(19) United States
(12) Patent Application Publication
(10) Pub. No.: US 2013/0277711 A1
(43) Pub. Date: Oct. 24, 2013

(54) Oscillation Free Fast-Recovery Diode

(71) Applicant: INTERNATIONAL RECTIFIER CORPORATION, El Segundo, CA (US)

(72) Inventors: Hsueh-Rong Chang, Hermosa Beach, CA (US); Jiankang Bu, Temecula, CA (US)

(73) Assignee: International Rectifier Corporation, El Segundo, CA (US)

(21) Appl. No.: 13/851,766

(22) Filed: Mar. 27, 2013

Related U.S. Application Data
(60) Provisional application No. 61/625,943, filed on Apr. 18, 2012.

(51) Int. Cl. H01L 27/04

(52) U.S. Cl. CPC H01L 27/04
USPC 257/140

(57) ABSTRACT

In one implementation, a diode providing a substantially oscillation free fast-recovery includes at least one anode diffusion formed at a front side of a semiconductor die, and a cathode layer formed at a back side of the semiconductor die. The diode also includes a drift region and a buffer layer situated between the drift region and the cathode layer to enable the substantially oscillation free fast-recovery by the diode. In one implementation, the buffer layer is N type doped using hydrogen as a dopant.

The present application claims the benefit of and priority to a pending provisional application entitled “Oscillation Free Fast-Recovery Diode,” Ser. No. 61/625,943 filed on Apr. 18, 2012. The disclosure in this pending provisional application is hereby incorporated fully by reference into the present application.

### BACKGROUND

### Background Art

Diodes, such as silicon PN junction diodes, are utilized in a variety of high current, high voltage applications. For example, diodes are often implemented as free-wheeling diodes in combination with power transistors in power control units installed in electric and hybrid electric vehicles.

In order to satisfy the performance requirements imposed by such demanding automotive applications, it is advantageous that the diodes utilized be fast, while concurrently exhibiting soft recovery characteristics. Those features are advantageous because they tend to reduce the turn-on losses of the power transistors to which the diodes are typically coupled, as well as to reduce voltage overshoot and oscillation, which are undesirable in power conversion applications. However, conventional solutions for producing diode soft recovery characteristics typically increase diode recovery time, thereby reducing diode speed and increasing transistor turn-on losses.

### SUMMARY

The present disclosure is directed to an oscillation free fast-recovery diode, substantially as shown in and/or described in connection with at least one of the figures, and as set forth more completely in the claims.

### BRIEF DESCRIPTION OF THE DRAWINGS

FIG. 1 shows an exemplary implementational environment for an automotive power control unit (PCU) including an insulated-gate bipolar transistor (IGBT) module utilizing substantially oscillation free fast-recovery diodes.

FIG. 2A shows a perspective view of an IGBT module including an IGBT die and a substantially oscillation free fast-recovery diode die, according to an exemplary implementation.

FIG. 2B shows a top view of the substantially oscillation free fast-recovery diode die of FIG. 2A, according to an exemplary implementation.

FIG. 3 shows an expanded view of a region of the exemplary oscillation free fast-recovery diode die of FIG. 2B, as though “seen through” a front metal.

FIG. 4 shows an exemplary cross-sectional view of a portion of a substantially oscillation free fast-recovery diode die, corresponding to a view along perspective lines 4-4, in FIG. 3.

FIG. 5 is a graph contrasting an exemplary reverse recovery achieved by a substantially oscillation free fast-recovery diode implemented according to the principles disclosed by the present application with oscillations generated by a conventional diode.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

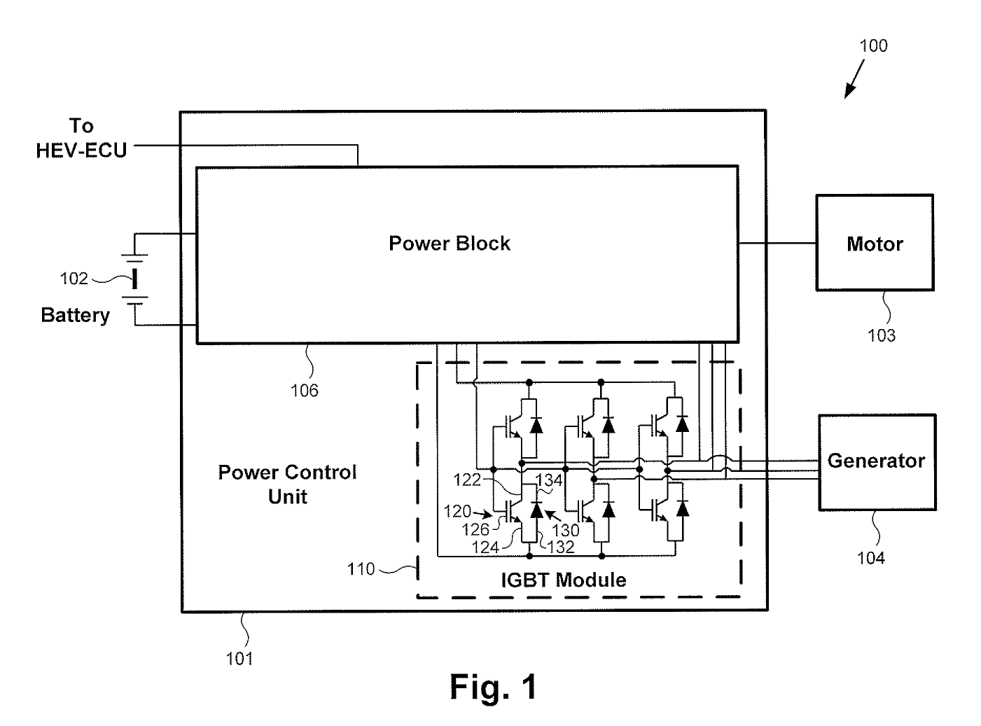

The demand for high voltage and high current in electric vehicles (EVs) and hybrid electric vehicles (HEVs) presents technical challenges for power conversion beyond those normally associated with automotive electrical systems. In addition, an increasing demand for fuel efficiency dictates that power control units (PCUs) implemented in EVs and HEVs be compact and light weight. FIG. 1 shows a PCU suitable for use in an HEV. As shown in FIG. 1, PCU 101 is implemented in HEV power train environment 100 and is typically coupled to the HEV electronic control unit (HEV-ECU), which is not shown in FIG. 1.

According to the example shown by FIG. 1, PCU 101 is implemented in HEV power train environment 100 in combination with battery 102, motor 103, and generator 104. PCU 101 includes power block 106 and insulated gate bipolar transistor (IGBT) module 110 including a plurality of IGBTs 120, with one exemplary IGBT 120 having collector 122, emitter 124, and gate 126 explicitly identified as such in FIG. 1. As further shown in FIG. 1, each IGBT 120 in IGBT module 110 has a substantially oscillation free fast-recovery diode 130 configured as a free-wheeling diode (FWD) coupled in antiparallel between IGBT collector 122 and IGBT emitter 124. In other words, IGBT 120 has substantially oscillation free fast-recovery diode 130 coupled in antiparallel such that anode 132 of substantially oscillation free fast-recovery diode 130 is coupled to emitter 124 of IGBT 120, and cathode 134 of substantially oscillation free fast-recovery diode 130 is coupled to collector 122 of IGBT 120. It is noted that only one exemplary representation of substantially oscillation free fast-recovery diode 130 having anode 132 and cathode 134 is explicitly identified as such in FIG. 1.

In order for IGBT module 110 in HEV power train environment 100 to achieve substantially optimal performance, substantially oscillation free fast-recovery diodes 130 should be fast, while concurrently exhibiting the advantageous characteristics of soft recovery without its associated drawbacks. As used herein, the expression “soft recovery” refers to diode recovery displaying a softness indicator “S” consistent with substantially oscillation free recovery. The softness indicator S is defined as the ratio t₂/t₁, where t₁ is the time interval between the beginning of reverse current flow through a diode and the occurrence of the maximum reverse current, and where t₂ is the time interval between the occurrence of the maximum reverse current and the time at which the reverse current first returns to zero. Diode recoveries in which S is less than 1.0 are undesirably associated with substantial oscillations. Diode recoveries in which S is greater than 1.0 typically do not display oscillations. However, the longer recovery times required for oscillation free conventional soft recoveries can undesirably increase switching losses.

The present application discloses substantially oscillation free fast-recovery diodes 130 configured to provide the substantially oscillation free recovery advantageously associated with soft recovery, but due to their faster recovery, substantially oscillation free fast-recovery diodes 130 do not produce the switching losses imposed by conventional soft recovery solutions. Those features, i.e., fast and substantially oscillation free recovery, are desirable in order to minimize the turn-on losses of IGBTs 120, as well as to reduce the voltage overshoot and oscillations which are commonly observed in conventional power conversion applications. Moreover, although conventional IGBT power modules typically use wirebonds at the anode connections of their conventional diodes, such connections are a common site of conventional IGBT module failure due to coefficient of thermal expansion (CTE) mismatch, and can be one of the main limiting factors for conventional IGBT module life.

In one implementation, substantially oscillation free fast-recovery diodes 130 can be fabricated in a die having solderable metals on the top and bottom surfaces (i.e., front and back sides) of each such die so as to offer a wirebond-less assembly option with increased reliability and reduced manufacturing cost. In addition, use of a solderable front metal (SFM) in lieu of a conventional wirebond connection at anodes 132 of substantially oscillation free fast-recovery diodes 130 permits double-sided cooling with a significantly larger heat exchange area, thus improving thermal management and enhancing the power handling capability of substantially oscillation free fast-recover diodes 130.

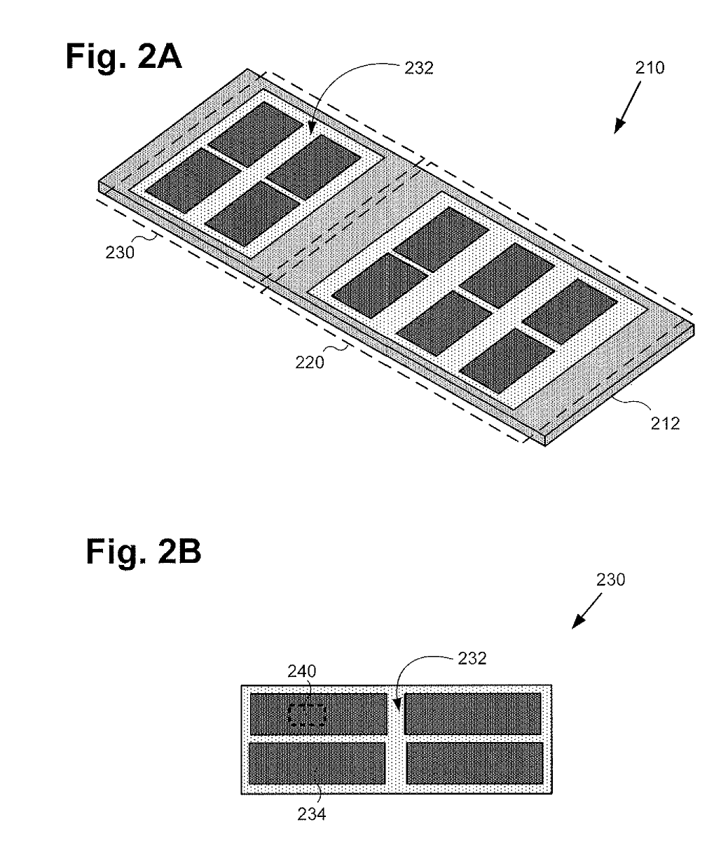

FIG. 2A shows a perspective view of IGBT module 210 including IGBT die 220, and substantially oscillation free fast-recovery diode die 230 having front side 232, according to one exemplary implementation. It is noted that, according to at least one implementation, substantially oscillation free fast-recovery diode die 230 may be a thin semiconductor die, such as a reduced thickness silicon die diced from an ultra-thin wafer (UTW). In one implementation, for example, substantially oscillation free fast-recovery diode die 230 is a silicon die having a thickness of less than approximately eighty micrometers (80 μm), such as a thickness in a range from approximately sixty-five micrometers to approximately seventy-five micrometers (approximately 65 μm to approximately 75 μm).

As shown in FIG. 2A, IGBT die 220 and substantially oscillation free fast-recovery diode die 230 are attached to substrate 212. For example, a back side of substantially oscillation free fast-recovery diode die 230 opposite front side 232 may be soldered to substrate 212 (back side of substantially oscillation free fast-recovery diode die 230 not visible from the perspective of FIG. 2A). Similarly, the back side of IGBT die 220 may be soldered to substrate 212 (back side of IGBT die 220 also not visible in FIG. 2A). Substrate 212 may be a Direct Bonded Copper (DBC) substrate, for example, which provides a good CTE match to silicon.

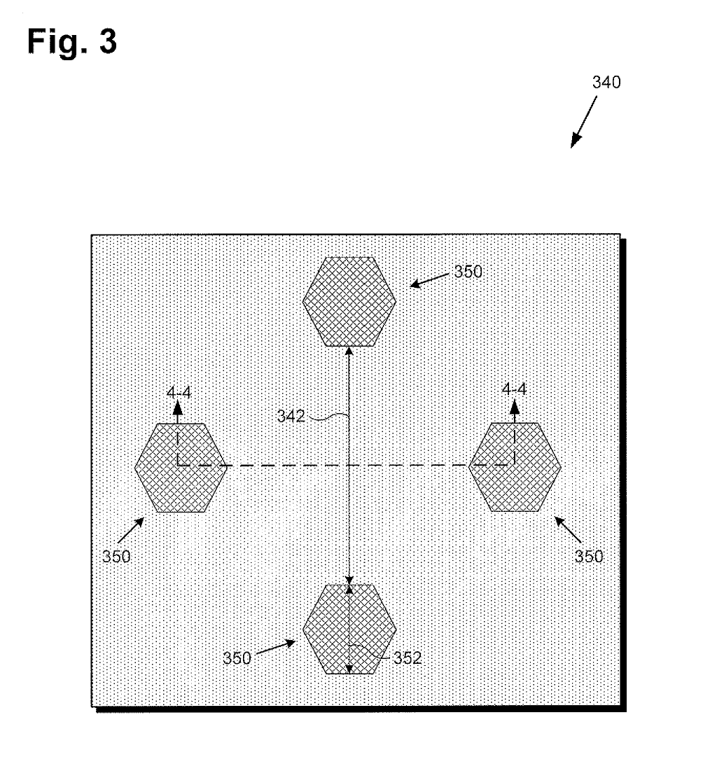

FIG. 2B shows a top view of substantially oscillation free fast-recovery diode die 230, according to one exemplary implementation. FIG. 2B shows SFM bodies 234 over front side 232 of substantially oscillation free fast-recovery diode die 230, with one exemplary SFM body 234 explicitly identified as such in FIG. 2B. In one implementation, SFM bodies 234 may be used to provide anode contacts for front side 232 of substantially oscillation free fast-recovery diode die 230. The solderable metal compositions used to form SFM bodies 234 may include titanium-nickel-silver (Ti—Ni—Ag), for example, or any solderable composition having suitably high thermal conductivity for effective cooling through front side 232 of substantially oscillation free fast-recovery diode die 230. Also shown in FIG. 2B is region 240, which corresponds to a portion of front side 232 of substantially oscillation free fast-recovery diode die 230 underlying SFM bodies 234 that will be shown and described in greater detail in conjunction with FIG. 3.

Referring to FIG. 3, FIG. 3 shows region 340 corresponding to an expanded view of region 240, in FIG. 2B, as though “seen through” one of SFM bodies 234 in that figure. Region 340, in FIG. 3, depicts an exemplary diode cell layout of substantially oscillation free fast-recovery diode die 230, in FIGS. 2A and 2B. As shown in FIG. 3, in one implementation, diode cells 350 may be configured as hexagonal diode cells 350, having cell diameter 352 and spacing 342 between adjacent cells. As a specific example, diode cells 350 may have cell diameter 352 in a range from approximately five micrometers to approximately twenty micrometers (approximately 5 μm to approximately 20 μm), and may be spaced one from another by spacing 342 in a range from approximately ten micrometers to approximately twenty micrometers (approximately 10 μm to approximately 20 μm), such as a spacing of seventeen micrometers (17 μm).

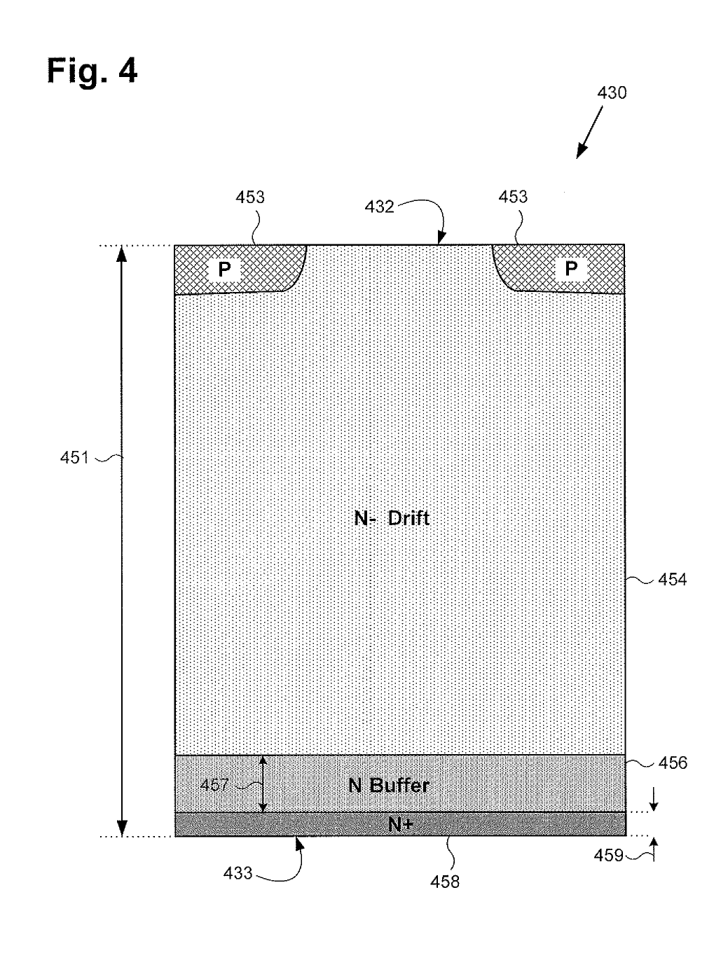

It is noted that although FIG. 3 represents diode cells 350 as hexagonal diode cells, in other implementations, diode cells 350 may be configured as square, circular, or stripe shaped diode cells, for example. It is further noted that, in some implementations, a substantially oscillation free fast-recovery diode according to the present inventive principles may be constructed without use of a multi-cell layout. Such an effectively cell free layout will be further described by reference to FIG. 4.

Continuing to FIG. 4, FIG. 4 shows an exemplary cross-sectional view of a portion of substantially oscillation free fast-recovery diode die 430, corresponding to a view along perspective lines 4-4, in FIG. 3. Substantially oscillation free fast-recovery diode die 430 corresponds to substantially oscillation free fast-recovery diode die 230, in FIGS. 2A and 2B. Moreover, substantially oscillation free fast-recovery diode die 430, in FIG. 4, corresponds in general to substantially oscillation free fast-recovery diodes 130, in FIG. 1.

As shown in FIG. 4, substantially oscillation free fast-recovery diode die 430, which may be a reduced thickness silicon die from an ultra-thin wafer, has front side 432, back side 433, and thickness 451. As noted above, thickness 451 may be less than approximately eighty micrometers (80 μm), and may be a thickness in a range from approximately sixty-five micrometers to approximately seventy-five micrometers (approximately 65 μm to approximately 75 μm), for example.

As further shown in FIG. 4, substantially oscillation free fast-recovery diode die 430 includes P type anode diffusions 453 formed in an upper portion of lightly doped N type drift region 454, at front side 432 of substantially oscillation free fast-recovery diode die 430. In addition, substantially oscillation free fast-recovery diode die 430 includes highly conductive N type cathode layer 458 formed at back side 433 of substantially oscillation free fast-recovery diode die 430, and N type buffer layer 456 situated between lightly doped N type drift region 454 and highly conductive N type cathode layer 458.

Although substantially oscillation free fast-recovery diode 430 die is shown to include a plurality of P type anode diffusions 453, corresponding to the multi-cell layout shown in FIG. 3, that need not be the case in all implementations. For example, in implementations in which substantially oscillation free fast-recovery diode die 430 has an effectively cell free or single cell layout, substantially oscillation free fast-recovery diode die 430 may include a single P type anode diffusion 453 extending across the substantial entirety of front side 432. Thus, more generally, a substantially oscillation free fast-recovery diode corresponding to substantially oscillation free fast-recovery diode die 430 will have at least one P type anode diffusion 453 at front side 432, and may have a plurality of P type anode diffusions 453.

P type anode diffusion(s) 453 may be formed in lightly doped N type drift region using any conventional techniques known in the art. For example, P type anode diffusion(s) 453 may be formed by boron (B) implantation through front side 432 of substantially oscillation free fast-recovery diode die 430, at a doping concentration of from approximately 5×10¹⁵ cm⁻³ to approximately 10¹⁸ cm⁻³, for instance. Substantially oscillation free fast-recovery diode die 430 may then undergo a UTW grinding process, for example, prior to being diced from an ultra-thin silicon wafer. Such a UTW grinding process may be followed by implantation through back side 433 to form N type buffer layer 456, and highly conductive N type cathode layer 458.

N type buffer layer 456 serves as a buffer region enabling substantially oscillation free fast-recovery by the diodes fabricated in substantially oscillation free fast-recovery diode die 430. N type buffer layer 456 has thickness 457, which may be in a range from approximately two micrometers to approximately ten micrometers (approximately 2 μm to approximately 10 μm), for example. According to one implementation, N type buffer layer is N type doped using hydrogen as a dopant. For example, N type buffer layer 456 may be formed by hydrogen (H) implantation through back side 433 of substantially oscillation free fast-recovery diode die 430, at a doping concentration of from approximately 5×10¹⁵ cm⁻³ to approximately 2×10¹⁷ cm⁻³, for instance. Other examples of dopants suitable for use in forming N type buffer layer 456 include phosphorus (P) and arsenic (As), for example.

Highly conductive N type cathode layer 458 has thickness 459, which may correspond to a thickness of approximately one micrometer (1 μm), for example. According to one implementation, highly conductive N type cathode layer 458 may be formed through phosphorus implantation at back side 433 of substantially oscillation free fast-recovery diode die 430, at a doping concentration of approximately 10¹⁸ cm⁻³, for example. Other examples of dopants suitable for use in forming highly conductive N type cathode layer 458 include arsenic and antimony (Sb), for example.

Thus, according to the implementation shown by FIG. 4, substantially oscillation free fast-recovery diode die 430 can be fabricated using a reduced thickness silicon die from an ultra-thin wafer, and using hydrogen implantation through back side 433 to produce buffer layer 456. In addition, fabrication of substantially oscillation free fast-recovery diode die 430 can subsequently include phosphorus implantation through back side 433 to form highly conductive N type cathode layer 458 providing a good ohmic cathode contact.

The diodes provided by substantially oscillation free fast-recovery diode die 430 produce a very low reverse recovery charge, thereby achieving a very low recovery loss, and do so substantially without oscillation. As a result, substantially oscillation free fast-recovery diode die 430 can advantageously provide enhanced durability and substantially oscillation free fast-recovery performance up to frequencies of approximately 200 kilohertz (200 kHz), for example, and can tolerate a junction temperature of up to approximately 175° C. In addition, substantially oscillation free fast-recovery diode die 430 can achieve its performance advantages while having a current rating (i.e., maximum current carrying capability) of up to approximately 600 amperes (600 A), and a breakdown voltage of up to approximately 750 volts (750 V), for example. Moreover, substantially oscillation free fast-recovery diode die 430 can be implemented using an SFM providing an anode contact over front side 432, so as to enable double-sided cooling for efficient performance at high power.

It is noted that although the specific implementation of substantially oscillation free fast-recovery diode die 430 shown in FIG. 4 is configured to have a breakdown voltage of up to approximately 750 V, in other implementations, a substantially oscillation free fast-recovery diode capable of tolerating higher voltages can be produced. For example, in one implementation, a substantially oscillation free fast-recovery diode according to the present inventive concepts can be configured to have a breakdown voltage of up to approximately 1700 volts (1700 V).

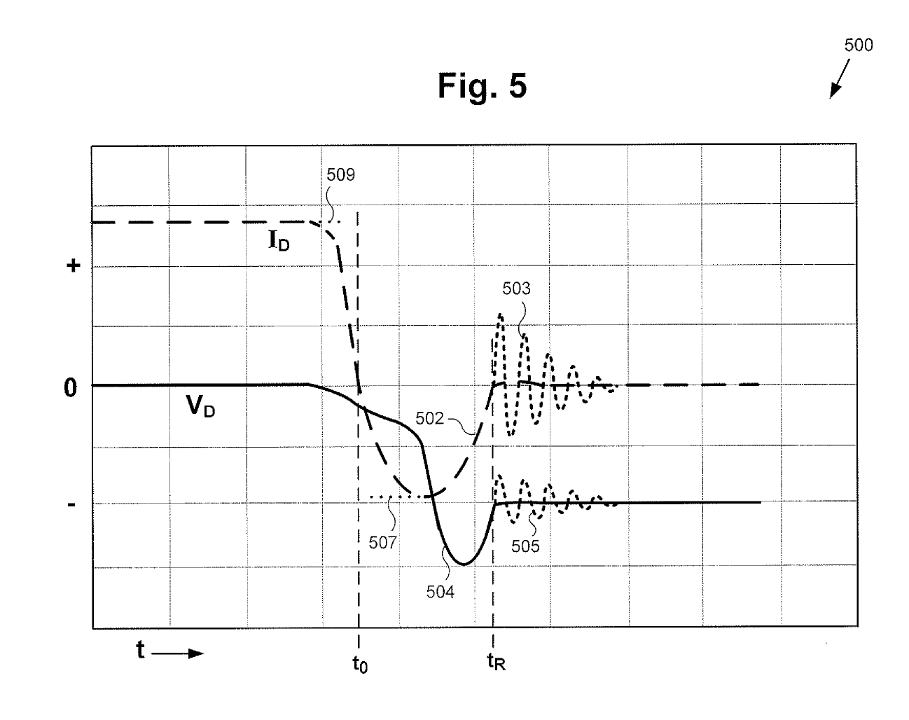

FIG. 5 shows a graph of the reverse recovery traces of a substantially oscillation free fast-recovery diode implemented according to the principles disclosed by the present application. Graph 500 shows substantially oscillation free fast-recovery diode current trace 502 and substantially oscillation free fast-recovery diode voltage trace 504. Also included in graph 500 are representations of the respective conventional diode current oscillations 503 and conventional diode voltage oscillations 505 generated during recovery by conventional diodes. It is noted that conventional diode current oscillations 503 and conventional diode voltage oscillations 505 are shown as overlays on respective substantially oscillation free fast-recovery diode current trace 502 and substantially oscillation free fast-recovery diode voltage trace 504, but are not produced as part of those substantially oscillation free fast-recovery diode traces.

As shown by graph 500, substantially oscillation free fast-recovery diode current trace 502 exhibits a small reverse recovery current. That is to say, the absolute value of maximum reverse current 507 of substantially oscillation free fast-recovery diode current trace 502 is small relative to the maximum diode current 509. As further shown by graph 500, substantially oscillation free fast-recovery diode current trace 502, as well as substantially oscillation free fast-recovery diode voltage trace 504, exhibit substantially no oscillation during recovery. By contrast, and as further shown by FIG. 5, conventional diode implementations typically, and undesirably, exhibit the substantial oscillations depicted by conventional diode current oscillations 503 and conventional diode voltage oscillations 505 during recovery.

Moreover, and in addition to displaying substantially oscillation free soft recovery characteristics, the recovery traces depicted in FIG. 5 are consistent with fast-recovery. For example, the time interval from t₀ to t_{R}, shown in graph 500, can be less than approximately 0.3 microseconds (3.0×10⁻⁷ s).

Thus, the present application discloses a substantially oscillation free fast-recovery diode that advantageously provides a soft recovery substantially without oscillations while concurrently providing a fast recovery in order to keep switching power loss at a desirably low level. Moreover, when implemented in combination with a solderable front metal to provide double-sided cooling, implementations of the present substantially oscillation free fast-recovery diode display enhanced power handling capability and improved durability in high current, high voltage applications.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A diode providing a substantially oscillation free fast-recovery, said diode comprising:
at least one anode diffusion formed at a front side of a semiconductor die;
a cathode layer formed at a back side of said semiconductor die;
a drift region and a buffer layer situated between said drift region and said cathode layer to enable said substantially oscillation free fast-recovery by said diode.

2. The diode of claim 1, wherein said buffer layer is produced by implanting an N type dopant through said back side of said semiconductor die.

3. The diode of claim 1, wherein said buffer layer is N type doped using hydrogen as an implant.

4. The diode of claim 1, wherein said diode is configured to tolerate a junction temperature up to approximately 175° C.

5. The diode of claim 1, wherein said diode has a breakdown voltage of up to approximately 1700 V.

6. The diode of claim 1, wherein said diode has a current rating of up to approximately 600 A.

7. The diode of claim 1, wherein an anode of said diode is coupled to an emitter of an insulated-gate bipolar transistor (IGBT), and a cathode of said diode is coupled to a collector of said IGBT.

8. The diode of claim 1, further comprising a solderable front metal (SFM) providing an anode contact over said front side of said semiconductor die.

9. The diode of claim 1, wherein said semiconductor die is a reduced thickness silicon die from an ultra-thin wafer (UTW).

10. The diode of claim 1, wherein said semiconductor die has a thickness of less than approximately 80 μm.

11. A diode providing a substantially oscillation free fast-recovery, said diode comprising:
at least one anode diffusion formed at a front side of a semiconductor die, and a cathode layer formed at a back side of said semiconductor die;
a drift region and a buffer layer situated between said drift region and said cathode layer, wherein said buffer layer is N type doped using hydrogen as a dopant.

12. The diode of claim 11, wherein said buffer layer is N type doped through said back side of said semiconductor die.

13. The diode of claim 11, wherein said diode is configured to tolerate a junction temperature up to approximately 175° C.

14. The diode of claim 11, wherein said diode has a breakdown voltage of up to approximately 1700 V.

15. The diode of claim 11, wherein said diode has a current rating of up to approximately 600 A.

16. The diode of claim 11, wherein said diode provides said substantially oscillation free fast-recovery up to frequencies of approximately 200 kHz.

17. The diode of claim 11, wherein an anode of said diode is coupled to an emitter of an insulated-gate bipolar transistor (IGBT), and a cathode of said diode is coupled to a collector of said IGBT.

18. The diode of claim 11, further comprising a solderable front metal (SFM) providing an anode contact over said front side of said semiconductor die.

19. The diode of claim 11, wherein said semiconductor die is a reduced thickness silicon die from an ultra-thin wafer (UTW).

20. The diode of claim 11, wherein said semiconductor die has a thickness of less than approximately 80 μm.
